(19) United States
(12) Patent Application Publication
(10) Pub. No.: US 2013/0164656 A1
(43) Pub. Date: Jun. 27, 2013

(54) PHOTOMASK AND MANUFACTURING METHOD THEREOF

(71) Applicants: Woo Jin Lee, Gyunggi-do (KR); Jae Hun Kim, Gyunggi-do (KR); Chung Mo Yang, Gyunggi-do (KR); Jin Uk Lee, Gyunggi-do (KR); Sang Su Hong, Gyunggi-do (KR); Young Woo Lee, Gyunggi-do (KR)

(72) Inventors: Woo Jin Lee, Gyunggi-do (KR); Jae Hun Kim, Gyunggi-do (KR); Chung Mo Yang, Gyunggi-do (KR); Jin Uk Lee, Gyunggi-do (KR); Sang Su Hong, Gyunggi-do (KR); Young Woo Lee, Gyunggi-do (KR)

(73) Assignee: SAMSUNG ELECTRO-MECHANICS CO., LTD., Gyunggi-do (KR)

(21) Appl. No.: 13/425,591

(22) Filed: Mar. 21, 2012

(30) Foreign Application Priority Data
Dec. 27, 2011 (KR) 1020110143606

(51) Int. Cl. G03F 1/76; G03F 1/00

(52) U.S. Cl. 430/5

(57) ABSTRACT

Disclosed herein are a photomask and a manufacturing method thereof. The photomask includes a transparent member, and a first mask and a second mask patterned on both sides of the transparent member, respectively.

### CROSS REFERENCE TO RELATED APPLICATION

This application claims the benefit of Korean Patent Application No. 10-2011-0143606, filed on Dec. 27, 2011, entitled “Photomask and the Manufacturing Method”, which is hereby incorporated by reference in its entirety into this application.

### BACKGROUND OF THE INVENTION

1. Technical Field

The present invention relates to a photomask and a manufacturing method thereof.

2. Description of the Related Art

In manufacturing a semiconductor, an LCD, and a touch panel, a photolithography process is used to form a fine electrode on a substrate.

Here, a photomask, which is one of the important elements of the photolithography process, serves to selectively expose a photosensitive portion plated on a substrate for the purpose of forming an electrode, thereby selectively forming an electrode on the substrate.

Also, a light source of an exposurer is adjusted for uniform exposure, or uniform exposure can be obtained through a photomask.

A prior art photomask is configured as a sectional mask to control diffracted or diffused light by contact exposure, or the like.

However, the prior art photomask has a problem in that only a single layer photomask is formed on a support base which only controls a fraction of diffracted or diffused light in the event of exposure.

Thus, accuracy of exposure is degraded and an electrode cannot be precisely formed.

### SUMMARY OF THE INVENTION

The present invention has been made in an effort to provide a photomask capable of reducing diffraction of light in the event of exposure, and a manufacturing method thereof.

The present invention has also been made in an effort to provide a photomask including masks having an identical pattern and formed on both sides of the photomask to thus effectively reduce diffraction of light that passes to the other side through one side of the photomask in the event of exposure, and a manufacturing method thereof.

The present invention has also been made in an effort to provide a photomask including masks having an identical pattern and formed on one side and the other side of the photomask such that a line width of the mask formed on one side of the photomask is different from that of the mask formed on the other side of the photomask, and a manufacturing method thereof.

According to a first preferred embodiment of the present invention, there is provided a photomask including: a transparent member; and a first mask and a second mask patterned on both sides of the transparent member, respectively.

The first mask and the second mask may be formed to have mutually the same pattern.

The first mask and the second mask may be formed to have mutually different line widths.

The transparent member may be made of glass or formed of a film.

The first mask and the second mask may be made of metal.

The first mask and the second mask may be made of metal silver formed by exposing and developing a silver salt emulsion layer.

The first mask and the second mask may be made of any one or more of copper (Cu), aluminum (Al), gold (Au), silver (Ag), titanium (Ti), palladium (Pd), chromium (Cr), and chromium oxide.

According to a second preferred embodiment of the present invention, there is provided a method for manufacturing a photomask, including: a metal layer formation step of stacking metal layers on both sides of a transparent member; a resist formation step of forming patterned resists on the metal layers; and a mask formation step of forming first and second masks patterned by exposing the metal layers through the resists.

The resist formation step may include: an exposing step of stacking a resist material on the metal layers and selectively exposing and curing the resist material; and a patterning step of selectively removing portions, which have not been cured, in the resist material to form a patterned resist.

The metal layer may be made of silver salt emulsion, and the mask formation step may include: a curing step of selectively exposing the silver salt emulsion to selectively form cured metal silver; and a patterning step of removing portions, which have not been cured, in the silver salt emulsion to form first and second patterned masks.

The method may further include: a resist removal step of separating the resists stacked on the first and second masks, after the performing of the mask formation step.

In the mask formation step, the first and second masks may be formed to have mutually the same pattern.

In the mask formation step, a line width of the first mask and that of the second mask may be formed to be different.

The transparent member may be made of glass or formed of a film.

The first mask and the second mask may be made of any one or more of copper (Cu), aluminum (Al), gold (Au), silver (Ag), titanium (Ti), palladium (Pd), chromium (Cr), and chromium oxide.

### BRIEF DESCRIPTION OF THE DRAWINGS

FIG. 1 is a cross-sectional view of a photomask according to an embodiment of the present invention;

FIG. 2 is a flow chart illustrating a process of a method for manufacturing a photomask according to another embodiment of the present invention;

FIGS. 3 through 6 are cross-sectional views showing sequential processes of the method for manufacturing a photomask according to another embodiment of the present invention; and

FIG. 7 is a view showing a usage state of a photomask manufactured according to the method for manufacturing a photomask according to another embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In describing the present invention, a detailed description of related known functions or configurations will be omitted so as not to obscure the gist of the present invention.

Hereinafter, preferred embodiments of the present invention will be described in detail with reference to the accompanying drawings.

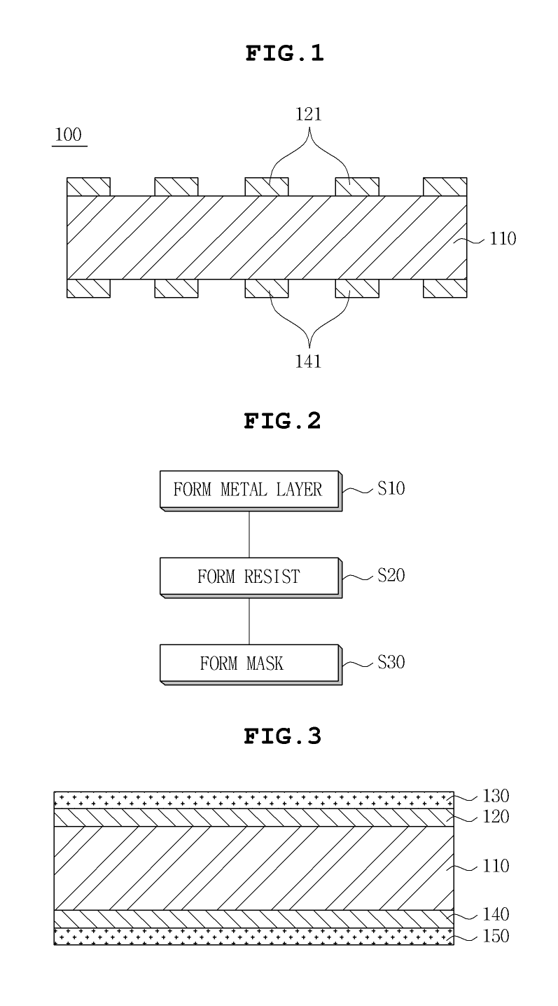

FIG. 1 is a cross-sectional view of a photomask according to an embodiment and another embodiment of the present invention.

With reference to FIG. 1, a photomask 100 according to an embodiment of the present invention includes a transparent member 110 and a first mask 121 and a second mask 141 formed on both sides of the transparent member 110.

Hereinafter, the photomask 100 according to an embodiment of the present invention will be described in detail with reference to FIG. 1.

First, with reference to FIG. 1, the transparent member 110 provides a support unit on which the first mask 121 and the second mask 141 are formed.

Also, the transparent member 110 may be made of glass or formed of a film.

Here, the film may be made of polyethylene terephthalate (PET), polycarbonate (PC), polymethylmethacrylate (PMMA), polyethylene naphthalate (PEN), polyether sulfone (PES), a cyclic olefin copolymer (COC), a triacetylcellulose (TAC) film, a polyvinyl alcohol (PVA) film, a polyimide (PI) film, polystyrene (PS), biaxially oriented polystyrene (BOPS) (which contains K-resin), or the like, but the present invention is not necessarily limited thereto.

Meanwhile, in order to activate both sides of the transparent member 110, both sides of the transparent member 110 may be treated with high frequency or a primer. The activation of both sides of the transparent member 110 can enhance adhesive strength between the transparent member 110 and the first mask 121 and the second mask 141.

Also, with reference to FIG. 1, the first mask 121 and the second mask 141 are selectively formed on both sides of the transparent member 110 to selectively block light when exposed.

Here, the first mask 121 and the second mask 141 are patterned to selectively block light when exposed, thus allowing light to selectively pass through the first mask 121 and the second mask 141.

Accordingly, an electrode layer 20 formed on a transparent substrate 10 may be selectively patterned by light, which has selectively passed through the first mask 121 and the second mask 141.

The first mask 121 and the second mask 141 may be formed to have mutually the same pattern, and here, the first mask 121 and the second mask 141 may have different line widths.

Here, the line width of the first mask 121 may be smaller than that of the second mask 141. In this case, for example, the line width of the first mask 121 may be 12% to 20% smaller than that of the second mask 141. However, the line width of the first mask 121 and that of the second mask 141 according to an embodiment of the present invention are not necessarily limited thereto.

The first mask 121 and the second mask 141 may be made of metal. Here, the metal may be one or more among copper (Cu), aluminum (Al), gold (Au), silver (Ag), titanium (Ti), palladium (Pd), chromium (Cr), and chromium oxide.

When the first mask 121 and the second mask 141 are made of copper (Cu), surfaces of the first mask 121 and the second mask 141 are blackened to prevent light from being reflected therefrom.

Also, the first mask 121 and the second mask 141 may be made of metal silver formed by exposing and developing a silver salt emulsion layer.

FIG. 2 is a flow chart illustrating a process of a method for manufacturing a photomask according to another embodiment of the present invention.

With reference to FIG. 2, a method for manufacturing a photomask according to another embodiment of the present invention includes a metal layer formation step (S10) of stacking metal layers 120 and 140 on both sides of the transparent member 110, a resist formation step (S20) of stacking resists 131 and 151 on the metal layers 120 and 140, and a mask formation step (S30) of selectively patterning the metal layers 120 and 140 to form the first and second masks 121 and 141.

The method for manufacturing a photomask according to another embodiment of the present invention relates to a method for manufacturing the photomask 100 according to one embodiment of the present invention, so the same reference numerals will be used for the same elements.

FIGS. 3 through 6 are cross-sectional views showing sequential processes of the method for manufacturing a photomask according to another embodiment of the present invention. FIG. 7 is a view showing a usage state of a photomask manufactured according to the method for manufacturing a photomask according to another embodiment of the present invention.

The method for manufacturing a photomask according to another embodiment of the present invention will be described in detail with reference to FIGS. 2 through 7.

With reference to FIGS. 2 and 3, in the step of forming the metal layers 120 and 140, the metal layers 120 and 140 are stacked on both sides of the transparent member 110 to form the metal layers 120 and 140.

Also, the transparent member 110 may be made of glass or formed of a film.

Here, the film may be made of polyethylene terephthalate (PET), polycarbonate (PC), polymethylmethacrylate (PMMA), polyethylene naphthalate (PEN), polyether sulfone (PES), a cyclic olefin copolymer (COC), a triacetylcellulose (TAC) film, a polyvinyl alcohol (PVA) film, a polyimide (PI) film, polystyrene (PS), biaxially oriented polystyrene (BOPS) (which contains K-resin), or the like, but the present invention is not necessarily limited thereto.

Meanwhile, in order to activate both sides of the transparent member 110, both sides of the transparent member 110 may be treated with high frequency or a primer. The activation of both sides of the transparent member 110 can enhance adhesive strength between the transparent member 110 and the metal layers 120 and 140, whereby adhesive strength of the first mask 121 and the second mask 141 obtained by patterning the metal layers 120 and 140 can be enhanced.

With reference to FIGS. 3 through 6, the resist formation step S20 includes an exposing step and a patterning step.

First, with reference to FIG. 3, in the exposing step, resist materials 130 and 150 are stacked to be formed on the metal layers 120 and 140 formed on both sides of the transparent member 110, respectively.

Also, light (ultraviolet ray) is irradiated toward the resist materials 130 and 150 by using an exposurer to selectively cure (or harden) the resist materials 130 and 150 positioned on both sides of the transparent member 110. Here, the resist materials 130 and 150 may be made of a polymer material.

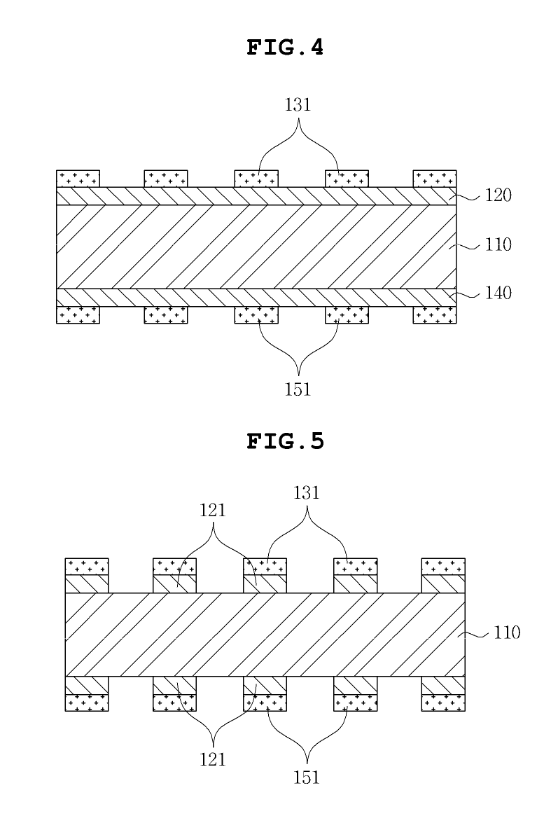

With reference to FIG. 4, in the patterning step, portions of the resist materials 130 and 150, which are not cured, are dissolved with a developing solution such as sodium carbonate (Na₂CO₃), potassium carbonate (K₂CO₃), or the like, so as to be removed.

Here, in order to form openings by selectively removing the resist materials 130 and 150, the resist materials 130 and 150 are patterned to form patterned resists 131 and 151.

With reference to FIG. 5, in the mask formation step (S30), the metal layers 120 and 140 exposed through the openings of the resists 131 and 151 are selectively exposed and patterned to form the first mask 121 and the second mask 141 made of a metallic material.

Also, in the patterning method through exposure, since the metal layers 120 and 140 are made of a silver salt emulsion (a silver salt emulsion layer), the silver salt emulsion is selectively exposed by an exposurer to form a pattern.

Here, the mask formation step (S30) includes a curing step and a patterning step.

In the curing step, the silver salt emulsion is selectively exposed and cured to form metal silver on a portion of the silver salt emulsion, which is selectively exposed.

Also, in the patterning step, portions of the silver salt emulsion, which have not been cured, are removed to allow metal silver, which has not been removed in the cured portions to form a pattern, thus forming the first mask 121 and the second mask 141.

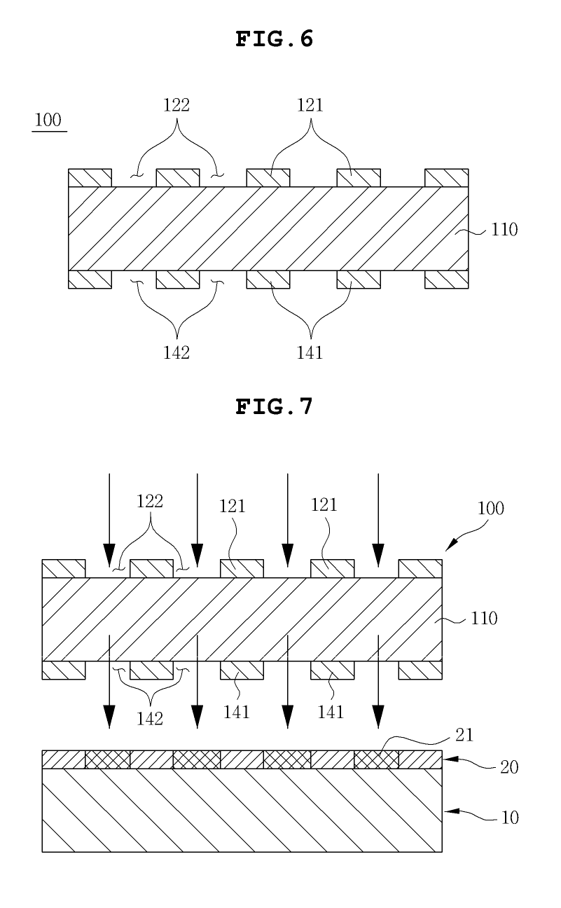

Meanwhile, with reference to FIG. 6, the method for manufacturing a photomask according to another embodiment of the present invention may further include a resist removal step of separating and removing the resists 131 and 151 stacked on the first mask 121 and the second mask 141.

The first mask 121 and the second mask 141 may be formed to have mutually the same pattern, and here, the first mask 121 and the second mask 141 may have different line widths.

Here, the line width of the first mask 121 may be smaller than that of the second mask 141. In this case, for example, the line width of the first mask 121 may be 12% to 20% smaller than that of the second mask 141. However, the line width of the first mask 121 and that of the second mask 141 according to an embodiment of the present invention are not necessarily limited thereto.

Thus, in the method for manufacturing a photomask according to another embodiment of the present invention, the photomask 100 in which the first mask 121 and the second mask 141 are formed to have the same pattern on both sides of the transparent member 110.

Here, in the photomask 100, when the electrode layer 20 stacked on the transparent substrate 10 is exposed to form a patterned electrode 21, it is positioned in the direction of a light source based on the transparent substrate 10 and light selectively passes therethrough.

Meanwhile, since the metal layers 120 and 140 are made of metal, the first mask and the second mask are made of the same metal.

Here, the metal may be one or more of copper (Cu), aluminum (Al), gold (Au), silver (Ag), titanium (Ti), palladium (Pd), chromium (Cr), and chromium oxide.

Hereinafter, the operation of the photomask 100 according to the method for manufacturing a photomask according to another embodiment of the present invention will be described.

First, with reference to FIG. 7, when the electrode layer 20 formed on the transparent substrate 10 is exposed, light is scanned to the electrode layer 20 stacked on the transparent substrate 10 through the openings 122 of the first mask 121 of the photomask 100, the transparent member 110, and the openings 142 of the second masks 141.

In this case, when light passes through the transparent member 110 through the openings 122 of the first mask 121, it travels straight or is refracted, and here, greatly refracted (diffracted) light may be reflected by the second mask 141 formed to have the same pattern as that of the first mask 121 so as to be filtered out.

Accordingly, light can be accurately irradiated to the electrode layer 20 through the photomask 100 in which the first mask 121 and the second mask 141 are identically formed on both sides thereof, the precisely patterned electrode 21 can be formed.

According to the preferred embodiments of the present invention, accuracy of exposure can be enhanced by reducing diffraction of light in the event of exposure.

Also, since the masks having the same pattern are formed on both sides of the photomask, diffraction of light which passes from one side of the photomask to the other side thereof can be effectively reduced in the event of exposure, whereby the accuracy of exposure can be enhanced and the electrode patterns can be precisely formed.

In addition, when the masks having the same pattern are formed on one side and the other side of the photomask, a line width of the mask formed on one side of the photomask and that of the photomask formed on the other side thereof are formed to be different to thereby adjust the quantity of light.

Although the embodiments of the present invention has been disclosed for illustrative purposes, it will be appreciated that the photomask and the manufacturing method thereof according to the invention are not limited thereby, and those skilled in the art will appreciate that various modifications, additions and substitutions are possible, without departing from the scope and spirit of the invention.

Accordingly, such modifications, additions and substitutions should also be understood to fall within the scope of the present invention.

What is claimed is:

1. A photomask comprising:
a transparent member; and
a first mask and a second mask patterned on both sides of the transparent member, respectively.

2. The photomask as set forth in claim 1, wherein the first mask and the second mask are formed to have mutually the same pattern.

3. The photomask as set forth in claim 2, wherein the first mask and the second mask are formed to have mutually different line widths.

4. The photomask as set forth in claim 1, wherein the transparent member is made of glass or formed of a film.

5. The photomask as set forth in claim 1, wherein the first mask and the second mask are made of metal.

6. The photomask as set forth in claim 5, wherein the first mask and the second mask are made of metal silver formed by exposing and developing a silver salt emulsion layer.

7. The photomask as set forth in claim 5, wherein the first mask and the second mask are made of any one or more of copper (Cu), aluminum (Al), gold (Au), silver (Ag), titanium (Ti), palladium (Pd), chromium (Cr), and chromium oxide.

8. A method for manufacturing a photomask, the method comprising:
a metal layer formation step of stacking metal layers on both sides of a transparent member;
a resist formation step of forming patterned resists on the metal layers; and
a mask formation step of forming first and second masks patterned by exposing the metal layers through the resists.

9. The method as set forth in claim 8, wherein the resist formation step includes:
an exposing step of stacking a resist material on the metal layers and selectively exposing and curing the resist material; and
a patterning step of selectively removing portions, which have not been cured, in the resist material to form a patterned resist.

10. The method as set forth in claim 8, wherein the metal layer is made of a silver salt emulsion, and
the mask formation step includes:
a curing step of selectively exposing the silver salt emulsion to selectively form cured metal silver; and
a patterning step of removing portions, which have not been cured, in the silver salt emulsion to form first and second patterned masks.

11. The method as set forth in claim 8, further comprising:
a resist removal step of separating the resists stacked on the first and second masks, after the performing of the mask formation step.

12. The method as set forth in claim 8, wherein, in the mask formation step, the first and second masks are formed to have mutually the same pattern.

13. The method as set forth in claim 12, wherein, in the mask formation step, a line width of the first mask and that of the second mask are formed to be different.

14. The method as set forth in claim 8, wherein the transparent member is made of glass or formed of a film.

15. The method as set forth in claim 8, wherein the first mask and the second mask are made of any one or more of copper (Cu), aluminum (Al), gold (Au), silver (Ag), titanium (Ti), palladium (Pd), chromium (Cr), and chromium oxide.
